(19) United States
(12) Patent Application Publication
(10) Pub. No.: US 2005/0048410 A1
(43) Pub. Date: Mar. 3, 2005

(54) Method of manufacturing a semiconductor device

(75) Inventor: Toshihiko Tanaka, Tokyo (JP)

Correspondence Address: Stanley P. Fisher;Reed Smith LLP, Suite 1400, 3110 Fairview Park Drive, Falls Church, VA, 22042-4503, US

(73) Assignee: Renesas Technology Corp.

(21) Appl. No.: 10/861,442

(22) Filed: Jun. 7, 2004

(30) Foreign Application Priority Data
Aug. 29, 2003 (JP) 2003-305879

(51) Int. Cl. G03F 7/00

(52) U.S. Cl. 430/313; 430/311; 430/396

(57) ABSTRACT

Along with increase in the operation speed and development in the integration degree of semiconductor devices, formation of fine gate patterns and fine and high-density patterns are required simultaneously. The prior art for coping with the requirement includes a full area slimming method and a shifter edge phase shift exposure method. The former method involves a problem that the width of the gate electrode wiring is reduced together with the gate pattern, tending to cause disconnection for the wiring area and lowering the yield. The latter method involves a problem that while restriction is imposed strongly on the layout due to inter-shifter interference or restriction on the arrangement of the shifters. A method of manufacturing a semiconductor device is provided for solving the problems together, in which a resist pattern is formed and then DUV or electron beam is applied to a desired portion for selectively slimming the resist.

### CLAIM OF PRIORITY

The present application claims priority from Japanese application JP 2003-305879, filed on Aug. 29, 2003, the content of which is hereby incorporated by reference into this application.

### BACKGROUND OF THE INVENTION

1. Field of the Invention

The present invention relates to a manufacturing method of semiconductor devices and, more in particular, it relates to a method of manufacturing semiconductor devices having gate electrodes formed finely at high-density.

2. Description of the Related Art

Since the operation speed of MOS transistors is improved more as the size of the gate becomes finer, miniaturization of the gate has been progressed particularly in recent years. As the length of the wiring is shortened, the operation speed is more improved in view of the time constant and this contributes to the saving of power consumption. Thus, improvement in wiring density has been proceeded. Further, a degree of integration of semiconductor devices has been increased by the formation of the fine patterns and high density. From the foregoings, the fine gate pattern and formation of fine pattern at high density have been demanded simultaneously.

With the situation described above, resolution has been improved so far by shortening the wavelength of light used for lithography and improving the numerical aperture (NA) of a lens used. However, as the numerical aperture of the lens has allowed to approach 1 and the exposure wavelength has reached a vacuum ultraviolet region at 193 nm by using an ArF excimer laser, the speed for the improvement of the resolution has not satisfy the requirement from the device, resulting in the need of a new artifice.

One of the methods is a full area slimming method. The full area slimming method is a method of forming at first a fine resist pattern at high density by usual lithography and then entirely refining the dimension uniformly by an asher or anisotropic etching. According to this method, it is possible to select the lithographic condition conforming the high-density fine pattern, which can reduce the pattern pitch and obtain a finer gate by slimming.

Another method is application of a super resolution exposure method typified by a shifter edge exposing method. The phase shift exposing method is a super resolution exposure method of forming a member producing a phase difference referred to as a phase shifter to a mask such that the phases of adjacent exposure areas are reversed, and applying exposure by way of the mask. This is a method of improving the resolution of enhancing the optical image contrast by utilizing the interference. This is referred to as a shifter edge exposure method since this utilizes a boundary between areas of adjacent phases, that is, the edges of the phase shifter in a case of preparing a fine gate. By the utilization of the phase change, the resolution is improved more than that in usual exposure and finer gate pattern can be resolved.

The methods described above have been adopted so far in a case of forming a fine gate that is difficult to be formed by usual exposure methods.

The full area slimming method is disclosed, for example, in Japanese Patent Laid-open No. 2001-265011. Further, the shifter edge exposing method is disclosed, for example, in Japanese Patent Laid-open No. 5-158244.

Problems with the full area slimming method and the shifter edge exposure method are to be described with reference to FIGS. 2 to 4 showing a pattern layout relevant to the gate. FIG. 2 shows the layout for an intended pattern. Reference numeral 22 denotes a gate wiring electrode pattern, 21 denote a gate area, and 23 denotes an electrode hole pattern for conduction. To operate a transistor at high speed, the gate pattern 21 is formed into a fine line. The wiring pattern for the gate electrode is laid out wider than the gate 21 with an aim of preventing disconnection and also lowering the resistance to some extent. Further, to increase the degree of integration, decrease the wiring resistance by shortening the wiring length, or reduce the chip area for cost down, the distance between the gate wiring electrodes is shortened to improve the pattern density. The electrode hole pattern 23 for establishing electrical conduction with the wiring formed in another layer on both ends of the gate electrode and on the gate electrode wiring 22.

FIG. 3 shows an example of a pattern formed by a full area slimming method. In usual exposure method, since the gate pattern 21 cannot be formed to a smaller size as desired, a resist pattern is once formed and then the pattern is thinned by applying an asher or the like thereto. That is, slimming is applied. While the gate pattern area 21 can be thinned to a desired size in this way, the gate electrode wiring 24 is also refined. Then, the wiring area becomes liable to be disconnected to lower the yield. Further, an alignment margin with the conduction hole electrode 23 on the gate wiring electrode is also reduced to result in a problem of increasing the frequency for the occurrence of alignment failure and deteriorating the electrical reliability.

FIG. 4 shows an example of a pattern layout formed by a shifter edge exposure method. Since a gate pattern 25 is formed by a phase shift method which is an intense super high image exposure method, a desired fine pattern can be formed by lithography. However, unlike the usual exposure method, it strongly undergoes restriction on the layout in view of the relation of inter-shifter interference or restriction on shifter arrangement. That is, gate arrangement is restricted to an optional place. Further, since it is formed by utilizing the phase change in the shifter edge area, only the closed loop pattern can be formed basically by the shifter edge exposure alone. Then, multiple exposure is conducted by using another mask to disconnect the closed loop area. The gate wiring electrode 22 is formed simultaneously. Since the gate area 25 and the gate wiring electrode 22 are formed by multiple exposure by using two masks, misalignment is caused between them. Then, the alignment margin with the conduction hole electrode 23 is reduced either for the gate pattern 25 or the gate wiring electrode 22 to result in lowering of the yield. The shifter edge exposure method involves the problem of the restriction on the pattern layout and decrease of the margin described above.

### SUMMARY OF THE INVENTION

The foregoing problem can be solved by forming a resist pattern and then slimming the resist selectively by directing deep ultraviolet light or an electron beam to a desired area.

Slimming means herein to reduce the wiring width to a level less than a resist pattern formed by exposure and this also includes, particularly, reducing the wire width by condensing the resist material without removing the resist in the invention.

If the resist material is condensed, there are provided advantageous features of improving etching resistance and thus compensating the etching mask insufficiency of a resist due to decrease of the thickness of the resist pattern layer caused in the slimming step.

According to the invention, a semiconductor device having an extremely fine gate and fine and highly integrated wirings, or having an extremely fine gate for a logic area and an extremely highly integrated gate for a memory area can be manufactured. This can improve the operation speed of a semiconductor device and improve the function by the improvement in degree of integration.

### BRIEF DESCRIPTION OF THE DRAWINGS

FIG. 1 is a conceptional diagram explaining the constitution of the invention;

FIG. 2 is a plan view for a main portion for explaining a pattern layout as an object of the invention;

FIG. 3 is a plan view for a main portion of a pattern showing a first example of pattern formation according to a conventional method;

FIG. 4 is a plan view for a main portion of a pattern showing a second example of pattern formation according to the conventional method;

FIGS. 5A to 5E are cross-sectional views for a main portion showing a manufacturing method according to the invention;

FIG. 6 is a plan view for a main portion showing a manufacturing method according to the invention;

FIG. 7 is a plan view for a main portion showing a manufacturing method according to the invention;

FIG. 8 is a plan view for a main portion showing a manufacturing method according to the invention;

FIG. 9 is a plan view for a main portion showing a manufacturing method according to the invention;

FIG. 10 is a diagram showing the constitution of an apparatus used in the invention;

FIG. 11 is a characteristic graph showing the feature of the invention:

FIG. 12 is a diagram showing the constitution of a second apparatus used in the invention;

FIG. 13 is a diagram showing the constitution of a third apparatus used in the invention;

FIG. 14 is a constitutional view showing the outline of a semiconductor device of the invention;

FIG. 15 is a plan view of a mask used in the invention;

FIG. 16 is a cross-sectional view showing the constitution of an apparatus according to the invention;

FIG. 17 is a step chart showing processing steps according to the invention;

FIG. 18 is a diagram showing an outlined constitution of an applied device according to the invention;

FIG. 19 is a diagram showing a pattern layout for a main logic area in the invention;

FIG. 20 is a diagram showing a pattern layout for a main SRAM mat area in the invention;

FIG. 21 is a diagram showing a pattern layout for a main SRAM peripheral circuit in the invention; and

FIG. 22 is a diagram showing a pattern layout according to the invention.

### DESCRIPTION OF THE PREFERRED EMBODIMENT

(Embodiment 1)

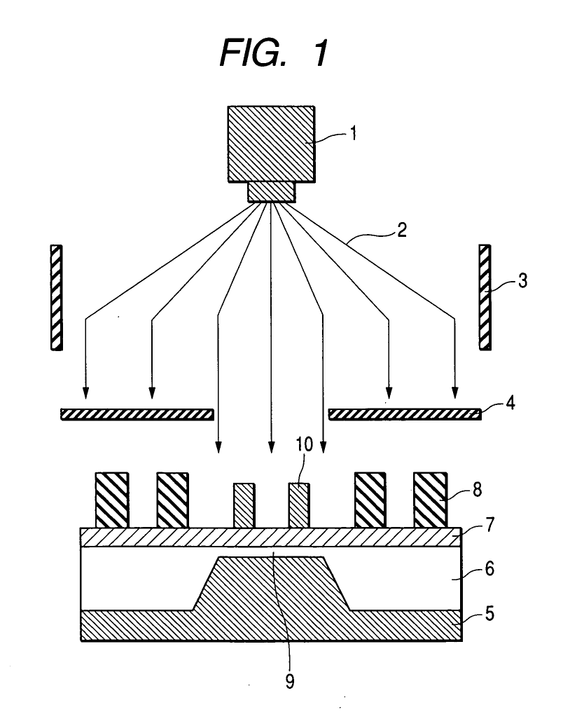

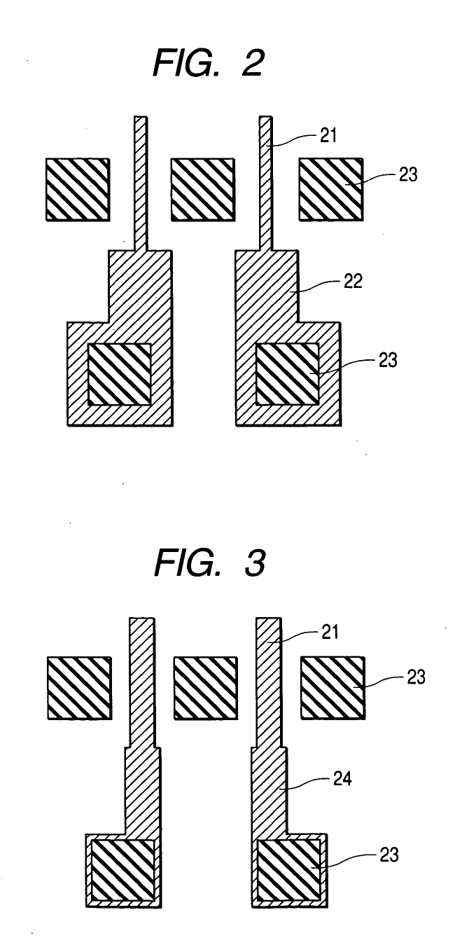

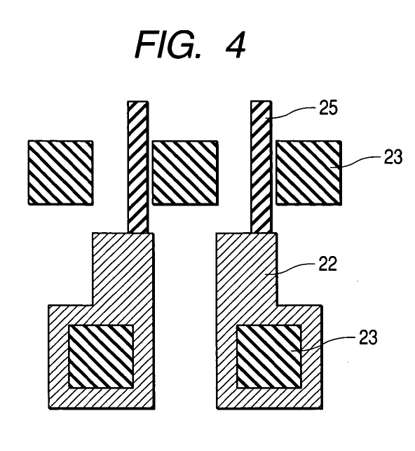

At first, the outline of a first embodiment is to be described with reference to FIG. 1. In FIG. 1, are shown an electron beam source 1, an electron beam 2, a collimate lens 3, a mask 4, a semiconductor substrate 5, an oxide layer 6, a polysilicon film 7, resist patterns 8 and 10 and a gate channel 9. The electron beam 2 emitted from the electron beam source 1 is collimated by the collimate lens 3, and directed vertically to the mask 4 having a window for a gate area. The mask 4 and the wafer are arranged close to each other, and the electron beam is directed selectively to the resist pattern 10 for the gate area. By the electron beam irradiation, the resist pattern 10 in the gate area is selectively shrunk compared with the resist pattern 8 other than the gate area.

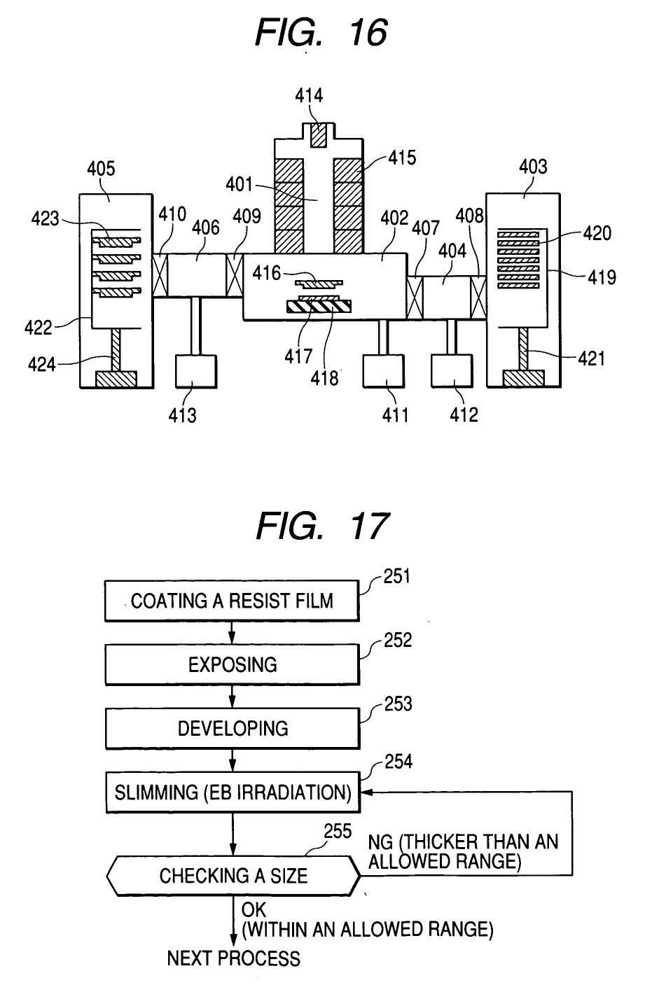

Then, the outline of an electron beam irradiation apparatus used for slimming is to be described with reference to FIG. 16, which is a cross sectional structural view of the apparatus. This apparatus mainly comprises an electron lens holder 401, an electron beam irradiation chamber 402, a wafer stocker 403, and a mask stocker 405. The wafer stocker 403 and the electron beam irradiation chamber 402 are in communication by way of a load lock room 404, and the mask stocker 405 and the electron beam irradiation chamber 402 are in communication by way of a load lock chamber 406. Shutters 407, 408, 409, 410 are located between each chamber. Vacuum pumps 411, 412, and 413 are connected to the electron beam irradiation rooms 402, and the load lock rooms 404 and 406, respectively. With this configuration, masks or wafers can be transferred from the outside to the electron beam irradiation chamber 402 while the vacuum degree is maintained in the electron beam irradiation chamber 402. An electron gun 414 and an electron lens system 415 are provided in the electron lens holder 401, while a mask 416, a wafer 417 and a wafer stage 418 are provided in the electron beam irradiation chamber 402. A mechanism for positional alignment between the mask 416 and the wafer 417 and for controlling the proximity distance between them is incorporated (not illustrated). A wafer carrier 419 is provided in the wafer stocker 403 and a mechanism capable of vertically moving an elevator 421 to take out a desired wafer 420 is incorporated. Further, a mask shelf 422 is provided in the mask stocker 405 and a mechanism capable of vertically moving a lift 424 to take out a desired wafer is incorporated.

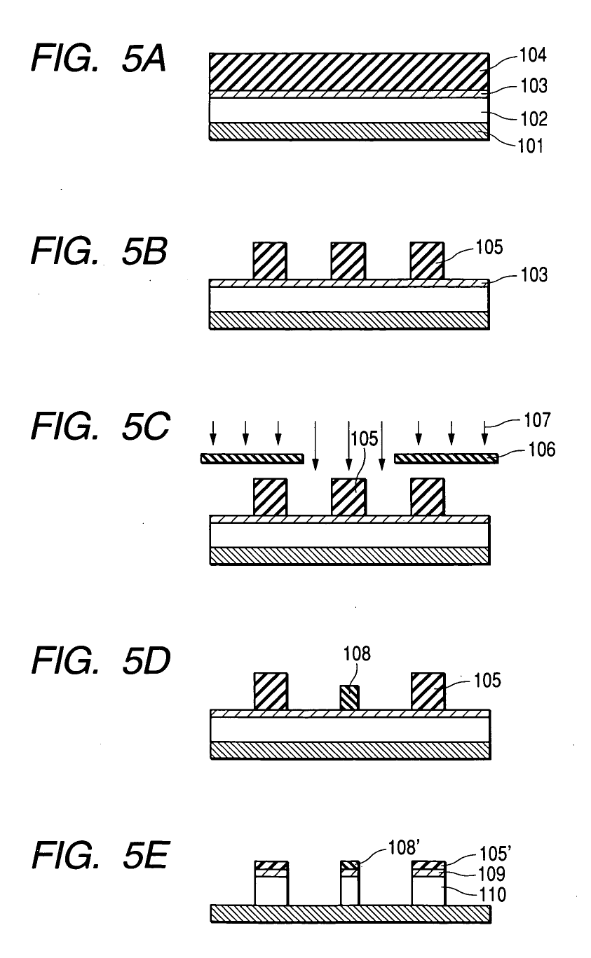

Then, details for the manufacturing steps are to be described with reference to FIGS. 5A to 5E, which are cross sectional structure views for a main portion. At first, as shown in FIG. 5A, an anti-reflection layer 103 and a resist film 104 are formed on a wafer in which a film 102 to be fabricated is formed on a substrate 101. While a polysilicon film is used as the film to be fabricated and an SiON film is used as the anti-reflection layer, they are not restrictive but a stacked film of tungsten and polysilicon may be used instead of the polysilicon film and an organic type anti-reflection coating (BARC) or the like may be used instead of the SiON film. An ArF resist made of a methacrylate resin was used as a resist. Then, as shown in FIG. 5C, a resist pattern 105 is formed on the anti-reflection layer 103 by a usual photolithographic method. An ArF scanner is used as an exposure apparatus. Then, an electron beam 107 is directed to a desired gate resist pattern 105,while the mask 106 having a window is allowed to approach the wafer. The acceleration voltage for the electron beam is set to 2.5 kV. If the acceleration voltage is as low as 200 V, the electron beam is trapped-only on the resist surface to provide less shrinking and resist hardening effect. If the acceleration voltage is excessively high, for example, as 100 kV, since most of electron beams passes through the resist without trapping, the efficiency is lowered extremely. Accordingly, the acceleration voltage is preferably from 500 V to 10 kV. If more importance is attached to the irradiation efficiency, 1 to 5 kV is particularly effective. As a result of selective irradiation of the electron beam, a fine gate resist pattern 108 can be formed while the resist pattern size for other area is kept as it is as shown in FIG. 5D. The gate resist pattern 108 is shrunk not only in the lateral direction for deciding the size but also in the longitudinal direction, that is, in the direction of the layer thickness. In this case, since the resist density is increased to harden the resist, the etching resistance is high. Accordingly, as shown in FIG. 5E, even after the anti-reflection layer and the film to be fabricated are etched, a resist 108′ remains at a gate pattern area of a thin resist layer thickness, which serves as a satisfactory etching mask for fabrication.

In the drawing, reference numeral 109 denotes the anti-reflection layer pattern after etching fabrication, 110 denotes the fabricated film pattern after fabrication, and 105′ denotes a resist pattern other than the desired gate area. As described above, a pattern in which only the desired gate area is selectively thinned can be formed by use of usual exposure with less restriction on the layout. Since the fine line can be formed through a process of electron beam selective irradiation, the exposure condition for the resist pattern can be conformed to the condition for forming a dense pattern such as line-and-space, for example, the condition of annular illumination or illumination with less coherency. Accordingly, the wiring pitch, etc. could be closer to provide an effect for improving the degree of integration. A pattern with a pattern pitch of 0.7 λ/NA or less and a gate width of 0.2 λ/NA can be formed for the dense wiring, λ representing the exposure wavelength and NA representing numerical aperture of the lens.

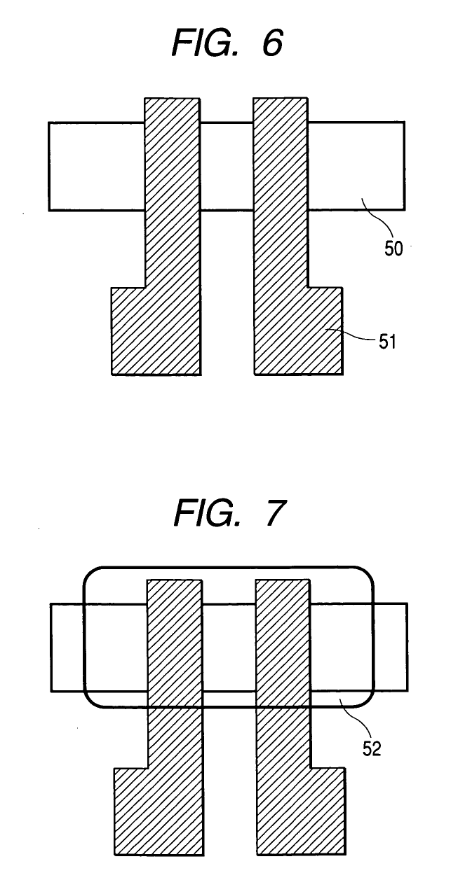

Then, the state of forming the pattern is to be described with reference to FIGS. 6 to 9 as viewed from the upper surface.

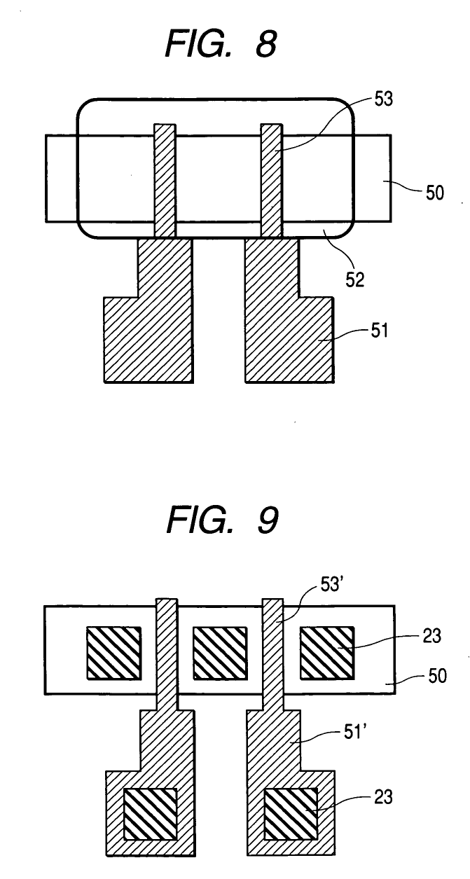

At first, as shown in FIG. 6, a gate resist pattern 51 containing a wiring area is formed such that a portion thereof is laid over an active region 50 by a usual exposure method. In this case, lithography is performed under exposure and illumination conditions suitable to the formation of a dense pattern. Then, as shown in FIG. 7, a mask having a window 52 for a desired gate area is applied and an electron beam is emitted to thin the gate resist pattern 53 as shown in FIG. 8. Then, fabrication is conducted as shown in FIG. 9 to form a gate 53′ and a gate electrode wiring 51′, followed by the formation of a conduction hole electrode 23. The production steps enables manufacture of a semiconductor device (1) having a fine gate, (2) providing less lowering of yield such as disconnection because of obtaining high density, a high degree of integration and desired wiring width, and (3) being capable of having alignment margin with the conduction hole electrode, thus providing high electric reliability and high yield

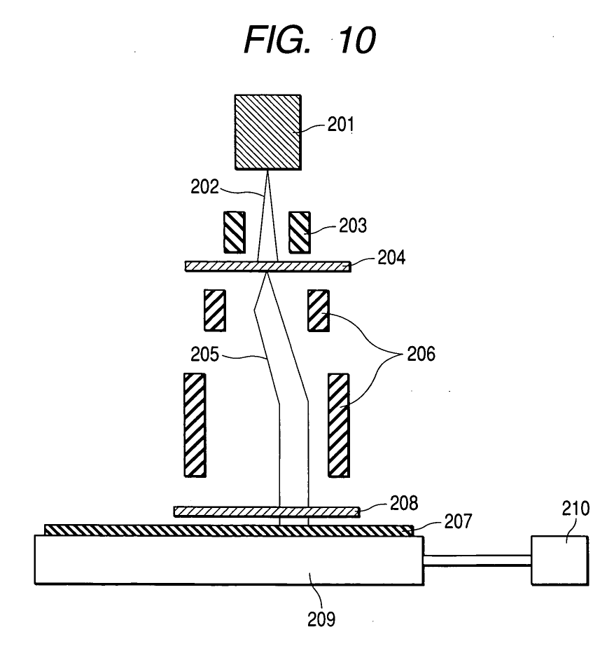

Then, an outline of an electron beam irradiation apparatus used herein is to be described with reference to FIG. 10. The electron beam irradiation apparatus comprises an electron source 201, an electron beam deflector lens 203, a selective aperture 204, an electron beam deflector lens and collimate lens 206, a wafer stage 209 and a wafer stage driving system 210. A wafer 207 is placed on the wafer stage 209 and a stencil mask 208 is placed adjacent to the wafer. The electron beam 202 emitted from the electron source 201 is deflected by the electron beam deflector lens 203 and turned ON and OFF through a selective aperture 204. The electron beam 205 passing through the selective aperture 204 is directed vertically to the mask 208 with the electron beam deflector lens and the collimate lens 206. Then electron beam passing through the window in the mask is incident on the wafer 207. The irradiation is conducted under step and repeat feeding of the wafer stage. Alternatively, the irradiation is conducted by also scan and step feeding of the wafer stage while scanning is performed by the electron bean deflector lens and the collimate lens 206.

Since a mask may be provided at the chip unit or the block unit in both of the methods, manufacture of the mask can be made simple and convenient. By the way, the irradiation was conducted on a 300 mm wafer by using the mask 208 of 4-inch size. In the apparatus, since it is no more necessary in this apparatus to collectively irradiate the entire wafer surface of a large diameter such as 300 mm wafer, the burden on the electron beam source or the electron beam lens is mitigated to make the constitution of the apparatus simple and convenient.

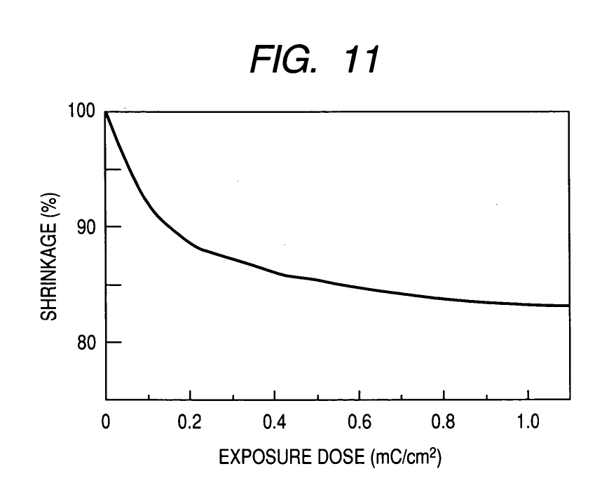

FIG. 11 shows the shrinkage of the resist pattern, that is, the amount of thinning of the pattern by electron beam irradiation. Characteristics in which although the pattern is thinned by the electron beam irradiation, the shrinkage is saturated with respected to the exposure dose provide sufficient controllability. Further, since the resist etching resistance is improved by about 80% under the irradiation at 0.4 mC/cm², a decrease in the thickness of the resist film by resist shrinkage caused no problem in the etching. While the methacrylate resin resist is used as the resist, this method shows an advantageous effect also by using a cyclo-olefin resin resist system, a novolac resin resist system or a phenolic resin resist system. However, methacrylate resin resist system shows a particularly high effect since the shrinkage caused by the electron beam irradiation is large and it causes shrinkage with less exposure dose. For example, the methacrylate resin resist system shows the shrinkage 5 to 10 times as large as the phenolic resin resist system.

(Embodiment 2)

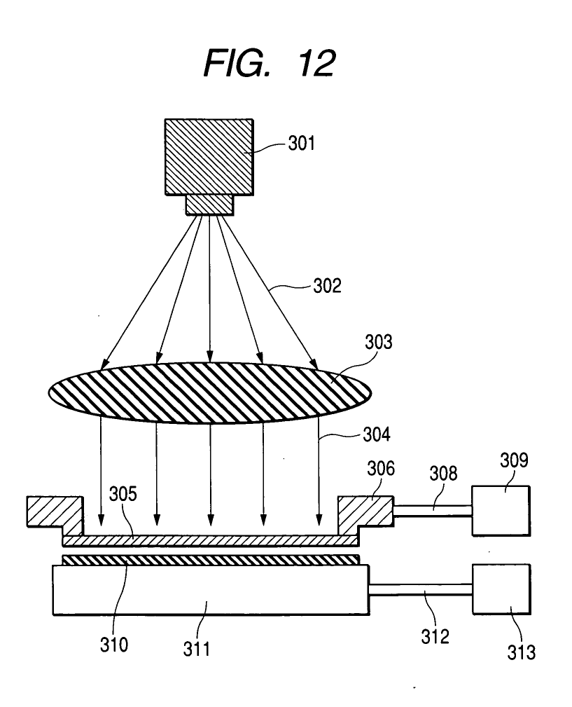

A second embodiment of an apparatus using deep ultraviolet light is to be described with reference FIG. 12, which is an outlined diagram.

The apparatus comprises a deep ultraviolet light source (DUV light source) 301, a lens 303, a mask holder 306, a mask driving system 309, a wafer stage 311, and a wafer stage driving system 313. The mask holder 306 and the mask driving system 309 are connected by way of a rod 308. Further, the wafer stage 311 and the wafer stage driving system 313 are also connected by way of a rod 312. A wafer 310 is placed on the wafer stage 311 and a mask 305 is placed under suction to the holder 306. The mask 305 is placed close to the wafer 310 and the positions for the mask 305 and the wafer 310 are controlled and adjusted by the respective driving systems 309 and 313.

Deep ultraviolet light 302 emitted from the deep ultraviolet light source 301 is adjusted into collimated light 304 and directed vertically to the mask 305. An excimer lamp for a wavelength of 222 nm is used for the deep ultraviolet light; however, light with a short wavelength from deep ultraviolet light to vacuum ultraviolet light by use of an excimer lamp for a wavelength of 172 nm, a mercury lamp for a wavelength of 254 nm or a KrF excimer laser for a wavelength of 248 nm can also be used. The excimer lamp has an advantageous feature that the lamp is inexpensive and easy to handle since it emits continuous light. When it was studied in details, ultraviolet light such as with a wavelength of 350 nm showed less effect for slimming or resist hardening and was not suitable to this method. When this apparatus was used as an illumination apparatus for selective resist slimming, a desired gate pattern could be reduced by about 20% compared with a case of not applying this method. In this embodiment, the description has been made of a collective transfer method in which the diameter is equal between the mask and the wafer but a step-and-repeat system as shown in Embodiment 1 can also be employed. The collective method has an advantageous feature in that the throughput is excellent, whereas the step-and-repeat system has an advantageous feature that alignment or mask preparation is facilitated. This method has an advantageous feature not requiring vacuum system and making the apparatus simple and convenient.

(Embodiment 3)

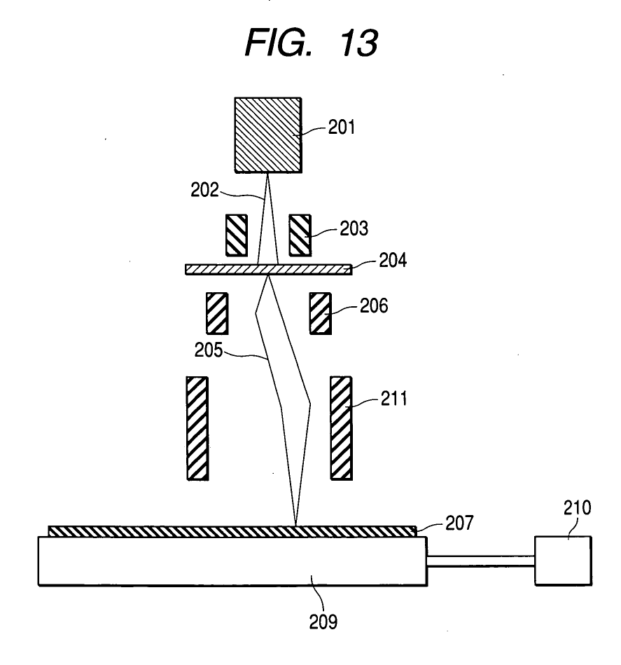

A third embodiment without using a mask is to be described with reference to FIG. 13, which is an outlined view of an apparatus.

The basic constitution of the apparatus is according to the irradiation apparatus shown in FIG. 10 for the first embodiment excepting that the mask is not used and, instead, an imaging lens system 211 is incorporated. In this apparatus, the electron beam is incident not by way of the mask but directly by way of the imaging lens system 211 on a desired gate area. This method has an advantegeous feature of not requiring manufacture of the mask and making it possible to reduce the number of steps. On the other hand, the first embodiment is excellent in view of the throughput in mass production since collective irradiation is possible at least on the block unit. Accordingly, the first embodiment is suitable for mass production whereas the third embodiment is suitable for a developing process or small-lot production.

(Embodiment 4)

A fourth embodiment is basically according to the third embodiment in which a size feedback method is introduced to ensure further higher dimensional accuracy. FIG. 17 shows a flow of processing steps of the invention. At first, a resist is coated on a wafer at 251, and usual pattern exposure is conducted at 252. Successively, usual development is conducted to form a resist pattern on the wafer at 253. Then, an electron beam is incident on a desired portion to apply slimming thereto at 254. While a method of direct irradiation not by way of the mask is used as the method of irradiating the electron beam, a method of irradiating every area individually by way of the mask may also be used. Then, an electron beam is emitted at a lower exposure dose than in the slimming step, and the reflected electron images are monitored to measure the size at a desired area (gate area) according to SEM at 255. When the size at the area is within an allowable range of the prescribed value, it is regarded as passing the check and it goes to the succeeding step. In a case where it is wider, electron irradiation is conducted again for slimming at 254 and the loop is repeated till the size falls within a desired range. According to this method, the dimensional accuracy in an area subjected to desired-slimming is further improved more than in the case of the third embodiment. Since the electron beam irradiation for slimming and the electron beam irradiation for size checking can be used in common within the electron beam irradiation apparatus, the efficiency is excellent.

(Embodiment 5)

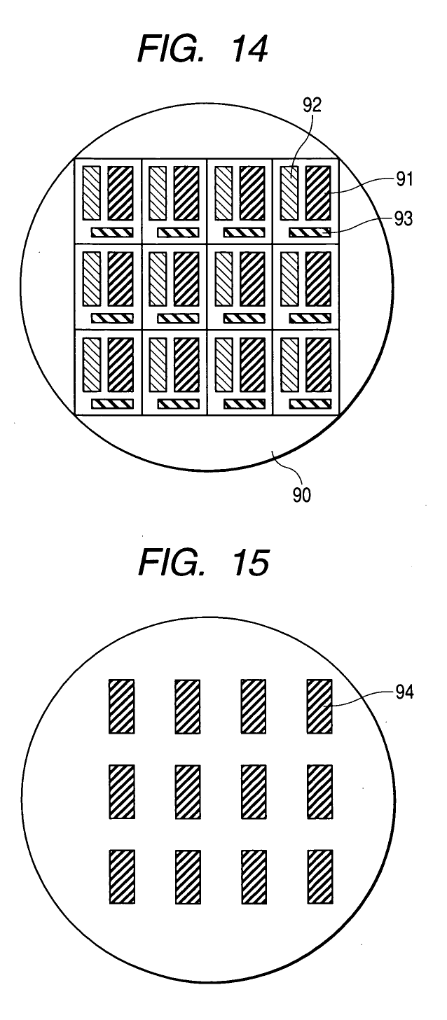

A fifth embodiment applied to a system LSI is to be described with reference to FIG. 14 and FIG. 15.

FIG. 14 is a schematic diagram of a wafer as viewed from above, in which are shown a wafer 90, a logic area 91, a memory area 92 and an I/O area 93. Gates are formed in each of the logic area, the memory area and the I/O area. Among them, a deep ultraviolet light is directed to the gate area for the logic area 91 in accordance with the second embodiment. In this case, a window is not disposed only in the gate area and the vicinity thereof but deep ultraviolet light is directed to a logic area by using a mask having an window in the logic area as shown at 94 in FIG. 15. This method has an advantageous feature of facilitating the manufacture of the mask and the alignment accuracy is sufficiently moderate. According to this method, a group of gates of a fine gate pitch in the memory area and a logic gate area of a fine gate can exist together at a high yield. Accordingly, a system LSI having a high operation speed for the logic area and having a memory with a high degree of integration can be formed at a high yield.

(Embodiment 6)

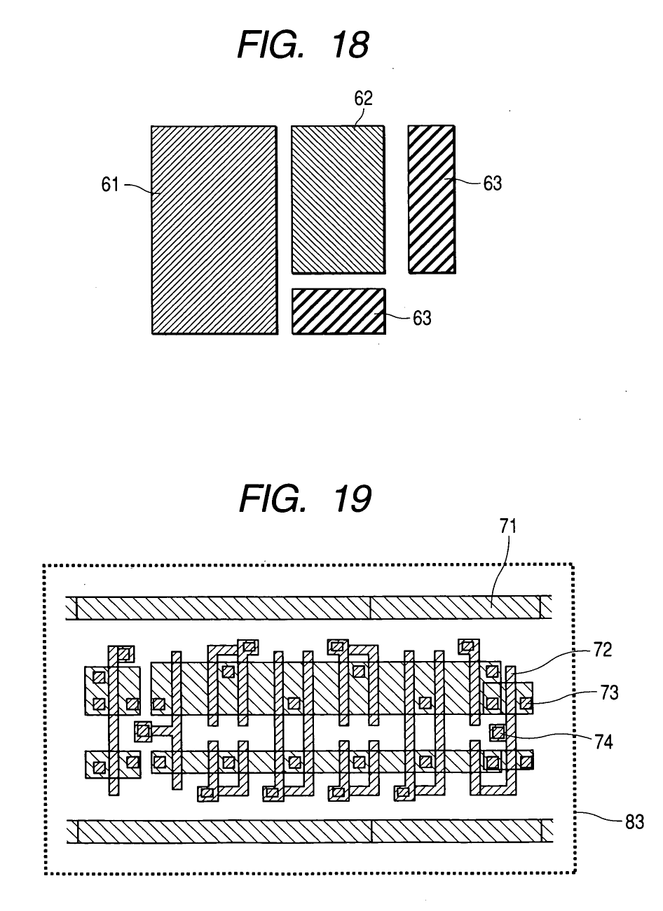

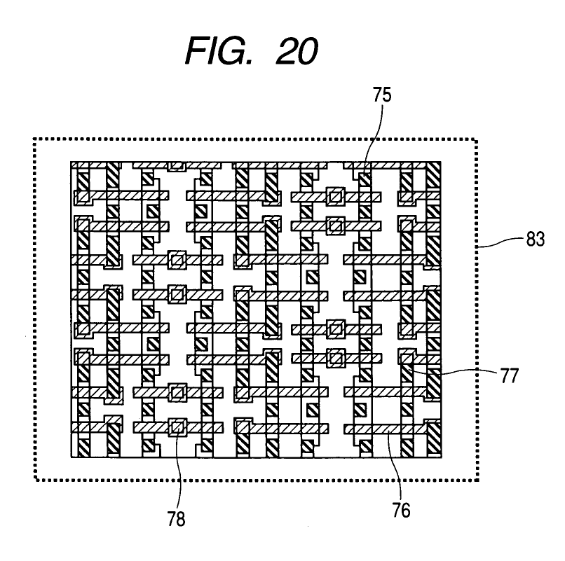

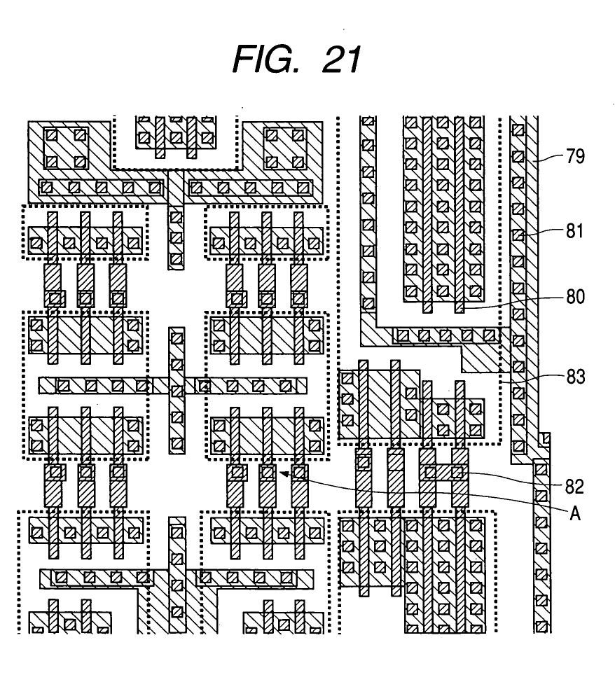

A sixth embodiment applied to a second system LSI is to be described with reference to FIGS. 18 to 21. FIG. 18 shows the arrangement for each functional area of an LSI as viewed from above, in which are shown a logic area 61, an SRAM mat area 62, and an SRAM periphery circuit area 63. FIGS. 19 to 21 show pattern layouts for a main logic, a main SRAM mat area, and a main SRAM peripheral circuit area, respectively, in which are shown diffusion layers 71, 75 and 79, gates (including gate wiring) 72, 76 and 80, and connection holes 73, 74, 77, 78, 81, and 82. Pattern slimming for the gate (wiring) is conducted by using a mask having such a window that an electron beam is directed to the entire surface of the logic area 61 and the SRAM mat area 62 and to a portion of the SRAM peripheral circuit area 63 among a series of pattern groups. In this case, the electron beam irradiation region for the SRAM periphery circuit area is a window shown at 83 in FIG. 21. By the slimming step, an extremely fine gate can be prepared. Further, a high function system LSI having extremely fine gates can be manufactured with no occurrence of conduction failure or failure such as wiring short circuit also in a dense gate wiring layout capable of obtaining neither adjacent distance for opposed patterns nor sufficient alignment margin between the conduction hole and the gate wiring in view of the positional relation for the conduction holes shown at A in FIG. 21.

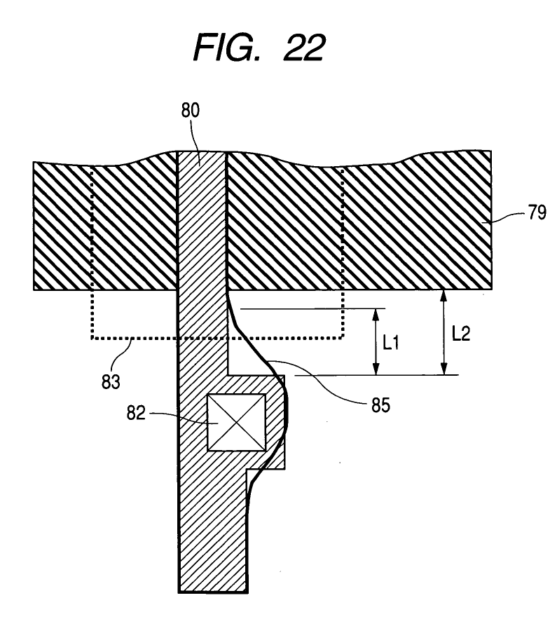

FIG. 22 shows an application example of this selective slimming method. A gate pattern 80 on the layout rides over the diffusion layer 79, and a gate pattern area in which the conduction hole 82 is formed for electroconduction with the gate is widened for taking an alignment margin. Owing to the non-linear layout, actual resist pattern transfer images have a shape in which a contact pad area expands moderately as shown at 85. Since accuracy and fineness are required for the gate on the diffusion layer 79, the gate pattern is used in a substantially linear state. Accordingly, the layout is made such that the contact pad area is spaced apart by a distance L2 from the diffusion layer. The distance L2 has a dimension of adding alignment accuracy to the gate pattern deformation distance L1. It is usually a distance of 150 nm or more. The irradiation area for slimming exposure, that is, the window 83 of the slimming mask is set so as to have a boundary between the contact pad and the diffusion layer. Since L2 is 150 nm or more, it is possible to ensure a sufficient size of slimming the gate in the diffusion layer 79 and with no slimming for the contact pad area when the alignment accuracy between the resist pattern and the mask (usually 50 nm) is taken into consideration.

### Descriptions for Reference Numerals Used in the Drawings are Shown Below.

1 . . . electron beam source, 201 . . . electron source, 2, 107, 202, 205 . . . electron beam, 3 . . . collimate lens, 4, 106, 305 . . . mask, 5 . . . semiconductor substrate, 6 . . . oxide layer, 7 . . . polysilicon film, 8, 10, 105 . . . resist pattern, 9 . . . gate channel, 21, 25 . . . gate area, 22 . . . gate wiring electrode pattern, 23 . . . hole pattern for electrode, 24 . . . gate wiring pattern, 50 . . . active area, 51, 53 . . . gate resist pattern, 52 . . . window, 101 . . . substrate, 102 . . . film to be fabricated, 103 . . . anti-reflection layer, 104 . . . resist layer, 108 . . . resist, 109 . . . anti-reflection layer pattern after etching fabrication, 110 . . . fabricated film pattern after fabrication, 203 . . . electron beam deflector lens, 204 . . . selective aperture, 206 . . . electron beam deflector lens and collimate lens, 207, 310 . . . wafer, 208 . . . stencil mask, 209, 311 . . . wafer stage, 210, 313 . . . wafer stage driving system, 211 . . . imaging lens system, 301 . . . deep ultraviolet light source (DUV light source), 302 . . . deep ultraviolet light, 303 . . . lens , 304 . . . collimated beam, 306 . . . mask holder, 308, 312 . . . rod, 309 . . . mask driving system, 401 . . . electron lens holder, 402 . . . electron beam irradiation chamber, 403 . . . wafer stocker, 404 . . . load lock chamber, 405 . . . mask stocker, 406 . . . load lock chamber, 407, 408, 409, 410 . . . shutter, 411, 412, 413 . . . vacuum pump, 414 . . . electron gun, 415 . . . electron lens system, 416 . . . mask, 417, 420, 423 . . . wafer, 418 . . . wafer stage, 419 . . . wafer carrier, 421, 424 . . . lift, 422 . . . mask shelf

1. A method of manufacturing a semiconductor device comprising the steps of:
forming a linear light sensitive coating pattern on a semiconductor substrate;
directing an energy ray to a portion of the linear light sensitive coating pattern thereby to thin the portion; and
transferring the linear light sensitive coating pattern thinned by irradiation of the energy ray to the semiconductor substrate.

2. A method of manufacturing a semiconductor device according to claim 1, wherein the energy ray is directed to the portion of the linear light sensitive coating pattern by way of a mask having a permeable area disposed in a shielded area.

3. A method of manufacturing a semiconductor device according to claim 1, wherein the linear light sensitive coating pattern is formed on an anti-reflection layer formed on the semiconductor substrate.

4. A method of manufacturing a semiconductor device according to claim 1, wherein a conductive film to be a gate is formed on the semiconductor substrate, the linear light sensitive coating pattern irradiated with the energy ray is a gate pattern and the transferring step includes etching the conductive film.

5. A method of manufacturing a semiconductor device according to claim 1, wherein the semiconductor substrate has a plurality of active areas in which transistors are formed and an insulation film formed between each active area, and the area to which the energy ray is directed contains the active area in which the linear light sensitive coating pattern is formed.

6. A method of manufacturing a semiconductor device comprising the steps of:
providing a semiconductor substrate in which a resist film is formed on a conductive film;
using a mask having a plurality of linear windows in a shielded area in which phases of exposing light passing the adjacent linear windows are reversed to each other, so as to transfer a pattern of the phase shift mask to the resist film for formation of a linear resist film pattern on the semiconductor substrate; and
directing an energy ray to a portion of the linear resist film pattern thereby to thin the portion.

7. A method of manufacturing a semiconductor device according to claim 6, wherein a pitch of lines in the linear resist film pattern is 0.7 λ/NA or less (in which λ represents the wavelength of the exposing light and NA represents the numerical aperture of the lens of the exposure apparatus).

8. A method of manufacturing a semiconductor device according to claim 6, wherein a width of a line in the linear resist film pattern after thinning by irradiation of the energy ray is 2 λ/NA or less (in which λ represents the wavelength of the exposing light and NA represents the numerical aperture of the lens of the exposure apparatus).

9. A method of manufacturing a semiconductor device according to claim 6, wherein the semiconductor substrate has a plurality of active areas and an insulative area formed between each active area and an area irradiated with the energy ray contains the active region formed with the linear resist film pattern.

10. A method of manufacturing a semiconductor device according to claim 6, wherein the linear resist film pattern after emission of the energy ray is transferred to the conductive film.

11. A method of manufacturing a semiconductor device according to claim 6, wherein the conductive film comprises polycrystal silicon.

12. A method of manufacturing a semiconductor device according to claim 6, wherein the conductive film comprises tungsten.

13. A method of manufacturing a semiconductor device according to claim 6, wherein the conductive film transferred with the linear pattern is provided with a contact portion in an area not irradiated with the energy ray.

14. A method of manufacturing a semiconductor device comprising the steps of;
forming a resist pattern for a gate electrode on a semiconductor substrate to be formed with a memory area and a logic area; and
directing an energy ray to a portion of the resist pattern formed in the logic area, thereby to make the portion thinner than the resist pattern formed in the memory area.

15. A method of manufacturing a semiconductor device according to claim 14, wherein a width of the resist pattern for the gate electrode irradiated with the energy ray has a size of a resolution limit of photolithography or less.

16. A method of manufacturing a semiconductor device according to claim 14, wherein the resist pattern is formed on an anti-reflection layer formed on the semiconductor substrate.

17. A method of manufacturing a semiconductor device according to claim 14, wherein the energy ray is a charged particle ray.

18. A method of manufacturing a semiconductor device according to claim 14, wherein the energy ray has a wavelength of 254 nm or less.

19. A method of manufacturing a semiconductor device according to claim 14, wherein the energy ray is directed to a portion of the resist pattern by way of a mask having a permeable area formed in a shielded area.

20. A method of manufacturing a semiconductor device according to claim 19, wherein the size of the mask is substantially identical with that of the semiconductor substrate.
